(19) United States
(12) Patent Application Publication
(10) Pub. No.: US 2022/0057709 A1
(43) Pub. Date: Feb. 24, 2022

(54) METHOD FOR APPROXIMATING IMAGING PROPERTIES OF AN OPTICAL PRODUCTION SYSTEM TO THOSE OF AN OPTICAL MEASUREMENT SYSTEM, AND METROLOGY SYSTEM TO THIS END

(71) Applicant: Carl Zeiss SMT GmbH, Oberkochen (DE)

(72) Inventors: Markus Koch, Neu-Ulm (DE); Daniel Pagel, Essingen (DE); Toufic Jabbour, Aalen (DE); Ralf Gehrke, Aalen (DE); Dirk Hellweg, Langenau (DE)

(21) Appl. No.: 17/519,906

(22) Filed: Nov. 5, 2021

Related U.S. Application Data
(63) Continuation of application No. PCT/EP2020/062836, filed on May 8, 2020.

(30) Foreign Application Priority Data
May 8, 2019 (DE) 102019206648.8

(51) Int. Cl. G03F 1/84; G03F 1/70; G06T 7/70; G06K 9/20; G06T 7/00

(52) U.S. Cl. CPC G03F 1/84; G03F 1/70; G06T 2207/30148; G06K 9/2027; G06T 7/0004; G06T 7/70

(57) ABSTRACT

For approximating imaging properties of an optical production system which images an object to imaging properties of an optical measurement system when imaging the object, which imaging properties arise from an adjustment displacement of at least one component (Mᵢ) of the optical measurement system, the following procedure is carried out: A production transfer function of the imaging is determined by the production system as a target transfer function. The production transfer function depends on an illumination setting for an object illumination. This determination is implemented for a target illumination setting. Furthermore, a measurement transfer function of the imaging is determined by the measurement system as an actual transfer function. The measurement transfer function likewise depends on the illumination setting for the object illumination. This determination is also implemented for the target illumination setting. An adjustment position (\vec{a}) of the at least one adjustment component (Mᵢ) of the measurement system is varied. This is implemented for minimizing a deviation of the production transfer function from the measurement transfer function. This results in an improvement of an accuracy of an approximation of imaging properties of the optical production system to properties of the optical measurement system, which can be part of a metrology system, in particular.

### CROSS-REFERENCE TO RELATED APPLICATIONS

This application is a continuation of and claims priority under 35 U.S.C. § 120 from PCT Application No. PCT/EP 2020/062 836, filed on May 8, 2020, which claims priority from German Application No. 10 2019 206 648.8, filed on May 8, 2019. The entire contents of the above applications are incorporated herein by reference.

### TECHNICAL FIELD

The invention relates to a method for approximating imaging properties of an optical production system to imaging properties of an optical measurement system. Further, the invention relates to a metrology system having a measurement system for performing such a method.

### BACKGROUND

A metrology system is known from US 2017/0131 528 A1 (parallel document WO 2016/0124 425 A2) and from US 2017/0132782 A1.

### SUMMARY

It is an aspect of the present invention to improve an accuracy of an approximation of imaging properties of an optical production system to imaging properties of an optical measurement system, which can be part of a metrology system, in particular.

According to the invention, this aspect is achieved by an approximation method having the features specified in claim 1.

According to the invention, it was recognized that, for the purposes of approximating imaging properties of the optical production system to those of the optical measurement system, there is an improvement in the accuracy if it is not a wavefront difference between the two optical systems that is minimized but if the focus is on minimizing a deviation of the transfer functions of the two optical systems. In addition to the wavefront, the respective transfer function also includes, in particular, the illumination setting during the object illumination, i.e., an illumination angle distribution during the object illumination. Taking account of the illumination setting in the approximation method improves the imaging property approximation. In particular, the imaging property approximation can be undertaken object-independently such that, in any case for a certain class of objects, an adjustment position of the at least one adjustment component, which arises on account of the approximation method, leads to the desired approximation of the imaging properties for all objects of this class. In particular, such objects can be real objects, i.e., objects with a real mask transmission function, and/or weak objects, i.e., objects whose diffraction spectrum is dominated by the zero order of diffraction such that the zero order of diffraction makes up more than 90%, for example, of the diffraction intensity in a certain diffraction angle range.

The target transfer function can be an optimal transfer function, i.e., in particular, an aberration-free transfer function. Alternatively, it is also possible to work with a given wavefront aberration of the optical production system when specifying the target transfer function. The optical production system, firstly, and the optical measurement system, secondly, can be two different optical systems. In principle, however, it is also possible for the optical production system and the optical measurement system to be a system with the same structure.

Using the respectively found adjustment position of the at least one adjustment component, in which the deviation of the transfer functions from one another is minimized, it is then possible, in particular, to generate or emulate a 3D aerial image of the object with the aid of the optical measurement system. For each z-coordinate of the aerial image, i.e., for each coordinate perpendicular to the image plane, it is then possible to choose a different adjustment position of the at least one adjustment component, which different adjustment position has respectively emerged during the approximation method when minimizing the transfer function deviation taking account of the wavefront of the production system corresponding to this z-coordinate.

Adjustable degrees of freedom can be those of translation and/or those of rotation. As an alternative or in addition thereto, it is possible to deform an adjustment component for adjustment purposes.

An adjustment of a plurality of degrees of freedom of one and the same adjustment component according to claim 2 increases the options of the approximation method for minimizing the transfer function deviation.

This applies accordingly if, according to claim 3, use is made of a plurality of adjustable adjustment components. This plurality of adjustment components, too, can in turn be adjustable in more than one degree of freedom.

A method according to claim 4 increases the use possibilities of the approximation method and, as a consequence, of an aerial image emulation by the measurement system, brought in line with the production system in the case of the corresponding illumination setting.

Usable illumination settings can be a conventional illumination setting, an annular illumination setting with a small or a large illumination angle, a dipole illumination setting, a multi-pole illumination setting, in particular a quadrupole illumination setting. Poles of such a multi-pole illumination setting can have different edge contours, for example leaflet or lens-element-shaped edge contours.

By way of example, the method according to claim 5 facilitates a specification of adjustment positions of the at least one adjustment component for the purposes of emulating 3D aerial images.

The use of a lookup table according to claim 6 simplifies an aerial image emulation for various illumination settings.

In the case of the specified illumination setting, the measurement system can then be brought into the assigned adjustment position of the adjustment components, for example following a query of the manipulator positions from the lookup table. Subsequently, imaging with the measurement system can then be performed for a given object, said imaging yielding, e.g., a 2D value contribution for a 3D aerial image of the production system to be emulated.

The advantages of a metrology system according to claim 7 correspond to those that have already been explained above with reference to the approximation method according to the invention.

The metrology system can be used to measure a lithography mask provided for projection exposure for producing semiconductor components with very high structure resolution, which is better than 30 nm, for example, and which can be better than 10 nm, in particular.

### BRIEF DESCRIPTION OF DRAWINGS

An exemplary embodiment of the invention is explained in greater detail below with reference to the drawing. In said drawing:

FIG. 1 schematically shows a projection exposure apparatus for EUV lithography, having an anamorphic projection exposure imaging optical unit for imaging a lithography mask as an optical production system;

FIG. 2 schematically shows a metrology system for determining an aerial image of the lithography mask, having a measurement imaging optical unit with an isomorphic imaging scale, an aperture stop with an aspect ratio not equal to 1 and at least one displaceable measurement optical unit adjustment component as an optical measurement system;

FIG. 3 scales, between a minimum value pmin and a maximum value pmax, a result of the wavefront difference between a wavefront of the optical production system and a wavefront of the optical measurement system in the case of a non-inventive optimization of the approximation of imaging properties of the two optical systems, which minimizes the wavefront difference on the basis of the minimization of the difference between the RMS values of the respective wavefront aberrations;

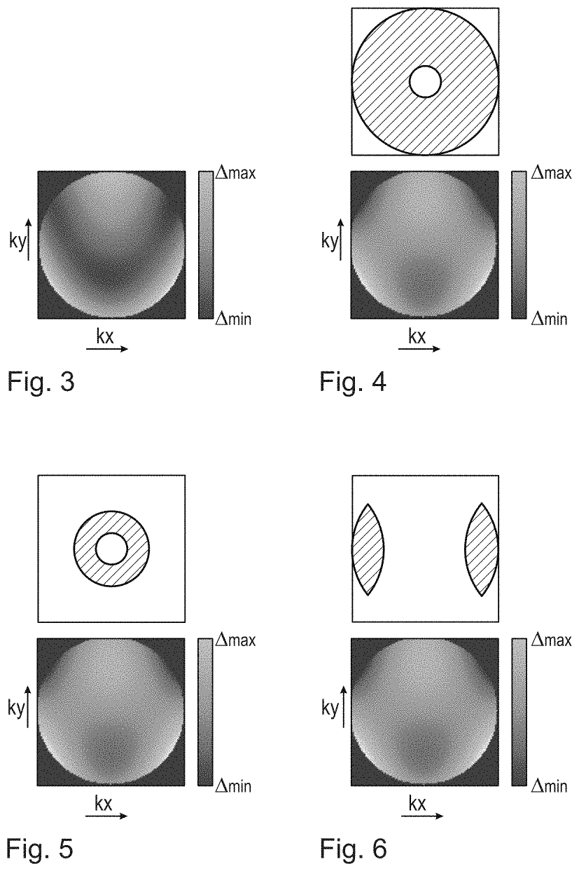

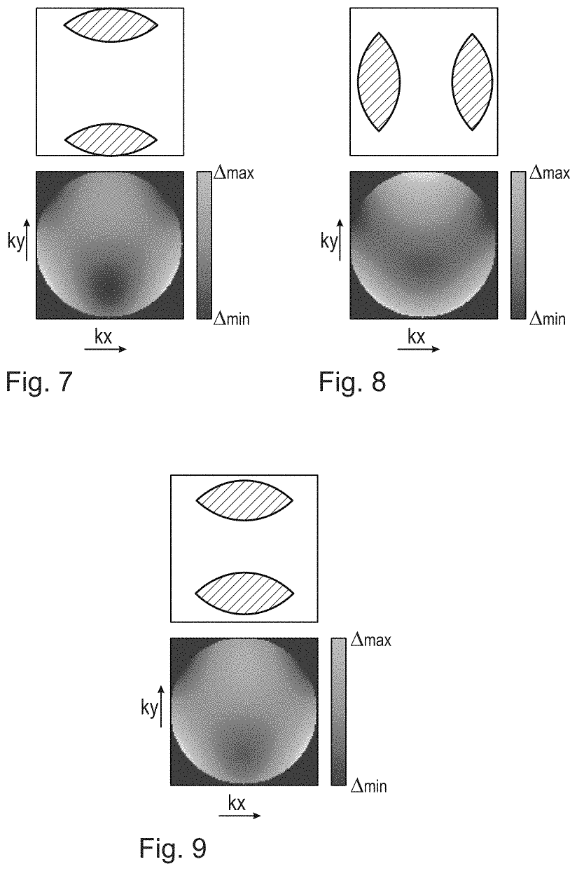

FIG. 4 shows at the top: an illumination setting for an object illumination of an object which is imaged, firstly, by the optical production system and, secondly, by the optical measurement system, embodied as a conventional setting with a masked region in the surroundings of a mean illumination angle, which can deviate from a perpendicular illumination, and
at the bottom: in an illustration similar to FIG. 3, an arising wavefront difference as a result of an optimization in which, instead of a minimization of the difference of the RMS values of the wavefronts of, firstly, the optical production system and, secondly, the optical measurement system, there is a minimization of the deviation of a production transfer function of the imaging by the production system from a measurement transfer function of the imaging by the measurement system, wherein the transfer functions are each dependent on the illumination setting;

FIG. 5 shows at the top: in an illustration similar to FIG. 4, at the top, a further illumination setting, embodied as an annular setting with small object illumination angles, i.e., object illumination angles that only deviate slightly from the mean illumination, and
at the bottom: in an illustration similar to FIG. 4, at the bottom, a wavefront difference for the illumination setting according to FIG. 5, at the top, as a result of the minimization of the deviation of the production transfer function from the measurement transfer function; and

FIGS. 6 to 9 show, in illustrations similar to FIGS. 4 and 5, at the top: further illumination settings in each case, in the form of different dipole illumination settings and at the bottom: the associated results of wavefront differences as a result of the minimization in each case of the deviation of a product transfer function from the measurement transfer function for the respective illumination setting.

### DETAILED DESCRIPTION

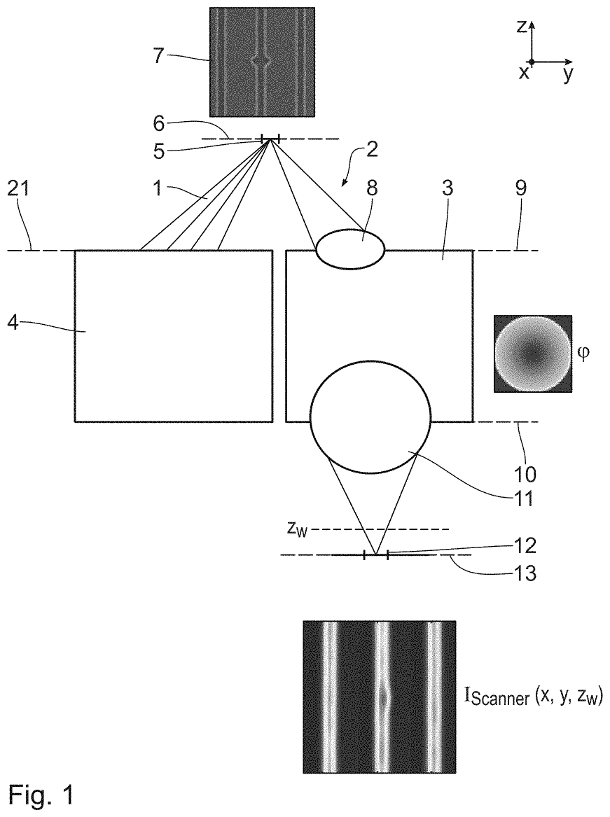

FIG. 1 shows, in a plane corresponding to a meridional section, a beam path of EUV illumination light or EUV imaging light 1 in a projection exposure apparatus 2 with an anamorphic projection exposure imaging optical unit 3, which is schematically reproduced by a box in FIG. 1. The illumination light 1 is generated in an illumination system 4 of the projection exposure apparatus 2, which is likewise represented schematically as a box. Together with the imaging optical unit 3, the illumination system 4 of the projection exposure apparatus 2 represents an optical production system.

The illumination system 4 contains an EUV light source and an illumination optical unit, neither of which are illustrated in detail. The light source can be a laser plasma source (LPP; laser produced plasma) or a discharge source (DPP; discharge produced plasma). In principle, a synchrotron-based light source may also be used, e.g., a free electron laser (FEL). A used wavelength of the illumination light 1 can lie in the range between 5 nm and 30 nm. In principle, in a variant of the projection exposure apparatus 2, a light source for another used light wavelength can also be used, for example for a used wavelength of 193 nm.

In the illumination optical unit of the illumination system 4, the illumination light 1 is conditioned so that a certain illumination setting of the illumination, i.e., a specific illumination angle distribution, is provided. A specific intensity distribution of the illumination light 1 in an illumination pupil of the illumination optical unit of the illumination system 4 corresponds to this illumination setting.

FIGS. 4 to 9 each show examples of such illumination settings at the top. The illuminated regions of the illumination pupil are illustrated with hatching in each case. FIG. 4, at the top, shows an example of a conventional illumination setting, in which practically all illumination angles are used for an object illumination, with the exception of illumination angles near the central incidence, which may deviate from a perpendicular illumination, on the object to be illuminated. FIG. 5, at the top, shows an annular illumination setting with, overall, small illumination angles, i.e., illumination angles near the central incidence, which in turn is excluded itself. FIGS. 6, at the top, to 9, at the top, show different examples of dipole illumination settings, wherein the individual poles each have a “leaflet” contour, i.e., an edge contour that approximately corresponds to the section through a biconvex lens element.

In order to facilitate the presentation of positional relationships, a Cartesian xyz-coordinate system is used hereinafter. In FIG. 1, the x-axis runs perpendicularly to the plane of the drawing and out of the latter. The y-axis runs towards the right in FIG. 1. The z-axis runs upwards in FIG. 1.

The illumination light 1 illuminates an object field 5 of an object plane 6 of the projection exposure apparatus 2 with the respectively set illumination setting, for example with one of the illumination settings according to FIGS. 4, at the top, to 9, at the top. A lithography mask 7 as object to be illuminated during production is disposed in the object plane 6; said lithography mask is also referred to as a reticle. A structure section of the lithography mask 7 is shown schematically in FIG. 1 above the object plane 6, which extends parallel to the xy-plane. This structure section is represented in such a way that it lies in the plane of the drawing of FIG. 1. The actual arrangement of the lithography mask 7 is perpendicular to the plane of the drawing of FIG. 1 in the object plane 6.

The illumination light 1 is reflected by the lithography mask 7, as illustrated schematically in FIG. 1, and enters an entrance pupil 8 of the imaging optical unit 3 in an entrance pupil plane 9. The employed entrance pupil 8 of the imaging optical unit 3 has an elliptic edge.

The illumination light or imaging light 1 propagates between the entrance pupil plane 9 and an exit pupil plane 10 within the imaging optical unit 3. A circular exit pupil 11 of the imaging optical unit 3 is located in the exit pupil plane 10. The imaging optical unit 3 is anamorphic and generates the circular exit pupil 11 from the elliptical entrance pupil 8.

The imaging optical unit 3 images the object field 5 into an image field 12 in an image plane 13 of the projection exposure apparatus 2. Below the image plane 13, FIG. 1 schematically shows an imaging light intensity distribution I_{scanner} which is measured in a plane spaced apart from the image plane 13 by a value zw in the z-direction, i.e., an imaging light intensity at a defocus value zw.

A wavefront aberration φ, illustrated schematically in FIG. 1 as a defocus deviation of an actual wavefront value from a target wavefront value (defocus =0), arises between the object plane 6 and the image plane 13, in particular on account of the components of the imaging optical unit 3.

The imaging light intensities I_{scanner} (x, y, z_{w}) at the various z-values around the image plane 13 are also referred to as a 3D aerial image of the projection exposure apparatus 2. The projection exposure apparatus 2 is embodied as a scanner. Firstly, the lithography mask 7 and, secondly, a wafer disposed in the image plane 13 are scanned, synchronously with respect to one another, during the projection exposure. As a result, the structure on the lithography mask 7 is transferred onto the wafer.

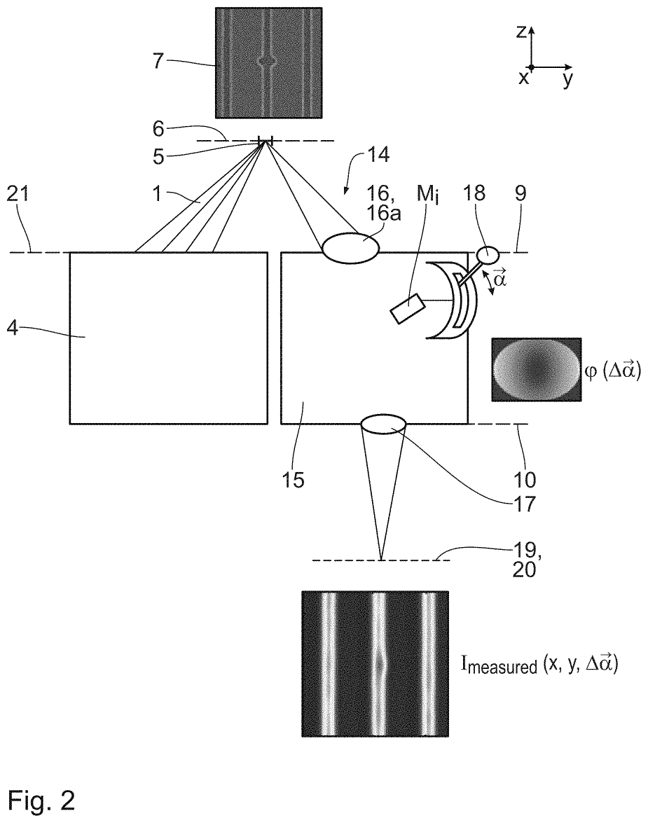

FIG. 2 shows a metrology system 14 for measuring the lithography mask 7. The metrology system 14 is used for the three-dimensional determination of an aerial image of the lithography mask 7 as an approximation to the actual aerial image I_{scanner} (x, y, z_{w}) of the projection exposure apparatus 2. To this end, use is made of a method in which imaging properties of the optical production system, i.e., of the illumination system 4 and of the imaging optical unit 3 of the projection exposure apparatus 2, are approximated to imaging properties of an optical measurement system of the metrology system 14 when imaging the object by way of an adjustment displacement of at least one component of the optical measurement system.

Components and functions, which have already been explained above with reference to FIG. 1 bear the same reference signs in FIG. 2 and will not be discussed in detail again.

In contrast to the anamorphic imaging optical unit 3 of the projection exposure apparatus 2, a measurement imaging optical unit 15 of the metrology system 14 is embodied as an isomorphic optical unit, i.e., as an optical unit with an isomorphic imaging scale. Apart from a global imaging scale, an entrance measurement pupil 16 is converted in this case, true to form, into an exit measurement pupil 17. Together with the illumination system 4, the measurement imaging optical unit 15 of the metrology system 14 forms an optical measurement system for object imaging.

The metrology system 14 has an elliptical aperture stop 16a in the entrance pupil plane 9. The embodiment of such an elliptical aperture stop 16a in a metrology system is known from WO 2016/012 426 A1. This elliptical aperture stop 16a generates the elliptical entrance measurement pupil 16 of the measurement imaging optical unit 15. Here, the inner edge of the aperture stop 16a specifies the external contour of the entrance measurement pupil 16. This elliptical entrance measurement pupil 16 is converted into the elliptical exit measurement pupil 17. An aspect ratio of the elliptical entrance measurement pupil 16 can be just as large as that of the elliptical entrance pupil 8 of the imaging optical unit 3 of the projection exposure apparatus 2. In respect of the metrology system, reference is also made to WO 2016/012 425 A2.

The measurement imaging optical unit 15 has at least one displaceable and/or deformable measurement optical unit adjustment component. Such a measurement optical unit adjustment component is illustrated schematically at Mᵢ as a mirror in FIG. 2. The measurement imaging optical unit 15 can comprise a plurality of mirrors M1, M2, . . . and can have a corresponding plurality Mᵢ, Mᵢ₊₁ of such measurement optical unit adjustment components. Exactly one degree of freedom can have an adjustable design in the respective measurement optical unit adjustment component Mᵢ. Alternatively, a plurality of displacement degrees of freedom could also be designed to be adjustable, i.e., displaceable and/or deformable.

\vec{a} A displaceability or manipulability of the displaceable and/or deformable measurement optical unit adjustment component Mᵢ is indicated schematically in FIG. 2 by way of a manipulator lever 18. A degree of freedom of the manipulation is indicated as a double-headed arrow in FIG. 2. Depending on a respectively set travel Δ\vec{a} of the displaceable and/or deformable measurement optical unit component Mᵢ, which is also referred to as a misalignment below, a wavefront aberration φ (Δ\vec{a}) arises, which is also schematically illustrated in FIG. 2, in a manner similar to FIG. 1.

A spatially resolving detection device 20, which could be a CCD camera, is disposed in a measurement plane 19 of the metrology system 14, which represents an image plane of the measurement imaging optical unit 15. In a manner similar to FIG. 1, a result of an intensity measurement I_{measured} (x, y, Δ\vec{a}) depending on the respective misalignment Aa of the displaceable and/or deformable measurement optical unit adjustment component Mᵢ is shown below the measurement plane 19 in FIG. 2.

As a rule, the imaging optical unit 3 of the optical production system differs from the measurement imaging optical unit 15 of the optical measurement system, which is elucidated in the example above by the difference between anamorphic imaging by the production system and isomorphic imaging by the measurement system. Other and/or additional differences between the imaging optical units of the production system and of the measurement system which lead to the imaging of the imaging optical unit of the optical production system differing from that of the optical measurement system are also possible.

The object of the approximation or convergence method explained below is that of bringing the imaging properties of the optical measurement system in line with the imaging properties of the optical production system of the projection exposure apparatus 2 by way of an adjustment displacement of the at least one measurement optical unit adjustment component Mᵢ in such a way that a correspondence between the aerial images I_{Scanner} of the optical production system and I_{measured} of the optical measurement system that is as good as possible arises for different objects to be imaged in the case of the resultant adjustment of the measurement imaging optical unit. Here, it was recognized that an optimization of such an approximation of the imaging properties can be improved by virtue of the goal not being minimization of the wavefront difference but that, in fact, minimization of the deviation of illumination setting-dependent transfer functions leads to a better result.

FIG. 3 shows, in exemplary fashion, the result that sets in in the case of a non-inventive approximation method, specifically in the case of a pure minimization of the difference between RMS wavefront values of, firstly, the imaging optical unit 3 of the projection exposure apparatus 2 and, secondly, the measurement imaging optical unit 15 of the metrology system 14. The value of the respective deviation is illustrated, plotted over the spatial frequencies kx, ky for the entire usable numerical aperture of the two optical units 3 and 15. A scale is specified to the right of this wavefront difference illustration, said scale permitting an assignment of the respective absolute difference value between a minimum value pmin and a maximum value pmax. The wavefront difference has a minimum value in an approximately V-shaped central section of the usable numerical aperture, which minimum value grows to higher differences in the lower and upper edge region of the usable aperture.

In the imaging property approximation method according to the invention, the difference between the wavefronts of the optical units 3, 15 is not optimized independently of the set illumination setting; instead, there is an illumination setting-dependent minimization of the difference between the transfer functions of, firstly, the optical production system of the projection exposure apparatus 2 (transfer function T_{P}) and, secondly, the measurement system of the metrology system 14 (transfer function T_{M}).

To this end, a production transfer function T_{P} of the imaging by the production system is initially determined as a target transfer function, with the production transfer function T_{P} being dependent on a certain, selected target illumination setting for an object illumination, for example for the illumination setting according to FIG. 4, at the top.

What is exploited here is that, depending on the spatial frequency coordinates k and depending on the component degrees of freedom a of the components of the associated imaging optical unit, a spectrum F of an aerial image, i.e., a Fourier transform of the aerial image, can be approximately described as follows:

F(\vec{k}, \vec{a})≈F₀+F₁(T₀(σ, A)−iT₁^{u}(φ, σ, A)+T₂^{g}(φ, σ, A))=F₀+F₁T (1)

This approximate relationship applies to real masks, i.e., to masks without an imaginary part of a mask transmission function. Moreover, this relationship applies to weak masks, i.e., to objects whose object spectrum is dominated by the zero order of diffraction.

Here, F₀ is a constant diffraction background of the mask. F₁ is a spatial frequency-dependent factor, which depends only on the mask and not on properties of the imaging optical unit. T₀, T₁ and T₂ are contributions to the transfer function T, which depend only on the properties of the imaging system and not on the mask.

Here, the following applies:

T₀(\vec{k})=2σ*A (2)

Here, σ is the specified illumination setting. A(\vec{k}) is an amplitude apodization form of the respective imaging optical unit (1 within the available numerical aperture; 0 outside). * denotes a convolution operator.

T₁^{u}(\vec{k})=T₁(\vec{k})−T₁(−\vec{k}) (3)

Here, T₁ (\vec{k})=σφ*A−σ*φ (4)

Here, φ is the respective wavefront of the imaging optical unit which, in the case of the measurement imaging optical unit 15, is dependent on the respective position \vec{a} of the at least one measurement optical unit adjustment component.

T₂^{g}(\vec{k})=T₁(\vec{k})−T₁(−\vec{k}) (5)

Here, T₂(\vec{k})=σφ* φ−½σφ²*A−½σ*φ² (6)

Determining an optical transfer function of an imaging optical unit for weak objects is described, for example, in the article “High-resolution transport-of-intensity quantitative phase microscopy with annular illumination” by C. Zuo et al., Scientific Reports, 7:7654/DOI: 10.1038/s41598-017-06837-1 (www.nature.com/scientificreports), published on Aug. 9, 2017.

Thus, in the case of weak real masks, a minimization of the difference between the transfer functions T for, firstly, the optical production system and, secondly, the optical measurement system leads to a minimization of the difference between the spectra and, as a consequence, to the desired minimization of the aerial images.

By inserting the determinable values for the illumination setting σ, the apodization function A and the wavefront φ, it is possible to determine the transfer functions T_{P}, T_{M} for, firstly, the optical production system (production transfer function) and, secondly, the optical measurement system (measurement transfer function).

By way of the wavefront φ, the measurement transfer function T_{M} depends on the respective adjustment position \vec{a} of the at least one measurement optical unit adjustment component Mᵢ. Now, using a numerical optimization method, a minimum of the deviation of the production transfer function T_{P} from the measurement transfer function T_{M} is searched for by varying the adjustment degrees of freedom of the at least one measurement optical unit adjustment component.

Once again, this minimization can be implemented as an RMS minimization, and so the following expression is minimized:

|T_{P}(\vec{k})−T_{M}(\vec{k})|² (7)

Examples of mask structures of the lithography mask 7 which were found to be suitable for this approximation method are line structures with a critical dimension (CD) ranging between 8 nm and 30 nm and a pitch ranging between 1:1 and 1:2. Here, it is possible to resolve defects with a typical size ranging between 2×2 nm² and 5×5 nm². Here, the defects on the lithography mask 7 may occur as elevations or as cutouts. Defocus values ranging up to 30 nm, for example +/−22 nm, can be taken into account here during the approximation method in the imaging properties of the optical production system. What emerges for these boundary conditions is that the minimization of the deviation of the transfer functions, as explained above, leads to better approximation results than a pure minimization of the deviation of the wavefronts, as explained above on the basis of FIG. 3.

The production transfer function T_{P} can be determined for various relative image positions, which deviate from an ideal relative image position (defocus equal to 0) in the image field of the projection system.

FIGS. 4 to 9 vividly show wavefront deviations between, firstly, the optical production system and, secondly, the optical measurement system when performing the above-described transfer function minimization for the various illumination settings respectively illustrated above. It was found that the wavefront deviations in FIGS. 4 to 9, at the bottom, by all means differ from one another and, in particular, regularly differ from the optimized wavefront difference according to FIG. 3. Despite these differences in the wavefronts, an aerial image deviation that, in relation to the deviation in the aerial images for the above-described mask examples, is significantly lower than in the case where the wavefront minimization is used respectively arises when using the transfer function minimization.

Depending on the illumination setting, a specific set of adjustment values arises for the measurement optical unit adjustment component or for the measurement optical unit adjustment components. The associated manipulator positions can be assigned to the respective illumination settings and stored in a lookup table. Then, if an optimum approximated aerial image of the optical measurement system should be produced in the case of a certain illumination setting, the set of manipulator settings matching the chosen illumination setting can be queried, and set, by querying the values of the lookup table.

What is claimed is:

1. A method for approximating
imaging properties of an optical production system which images an object
to imaging properties of an optical measurement system when imaging the object, which imaging properties arise from an adjustment displacement of at least one adjustment component (Mᵢ) of the optical measurement system,
including the following steps:
determining a production transfer function (T_{P}) of the imaging by the production system as a target transfer function, the production transfer function (T_{P}) depending on an illumination setting (σ) for an object illumination, for a target illumination setting,
determining a measurement transfer function (T_{M}) of the imaging by the measurement system as an actual transfer function, the measurement transfer function (T_{M}) depending on the illumination setting (σ) for the object illumination, for the target illumination setting,
varying an adjustment position (\vec{a}) of the at least one adjustment component (Mᵢ) of the measurement system for minimizing a deviation of the production transfer function (T_{P}) from the measurement transfer function (T_{M}).

2. The method of claim 1, wherein a plurality of degrees of freedom of the adjustment component (Mᵢ) of the measurement system are adjusted.

3. The method of claim 1, wherein a plurality of adjustment components (Mᵢ) of the measurement system are adjusted.

4. The method of claim 1, wherein the method is performed for various illumination settings (σ) which are used for the production process with the production system.

5. The method of claim 1, wherein the production transfer function (T_{P}) is determined for various relative image positions (z_{w}), which deviate from an ideal relative image position in an image field of the production system.

6. The method of claim 1, comprising assigning the manipulator positions of the at least one adjustment component (Mᵢ) to the respective illumination setting (σ) and storing the associated data in a lookup table.

7. A metrology system having a measurement system for performing the method of claim 1,
comprising an illumination system with an illumination optical unit for illuminating with a specified illumination setting (σ) the object to be examined,
comprising an imaging optical unit for imaging a section of the object into a measurement plane, the imaging optical unit having at least one adjustment component which is displaceable by way of an adjustment manipulator in terms of at least one degree of freedom of translation and/or rotation, and
comprising a spatially resolving detection device, disposed in the measurement plane.

8. The method of claim 2, wherein a plurality of adjustment components (Mᵢ) of the measurement system are adjusted.

9. The method of claim 2, wherein the method is performed for various illumination settings (σ) which are used for the production process with the production system.

10. The method of claim 3, wherein the method is performed for various illumination settings (σ) which are used for the production process with the production system.

11. The method of claim 2, wherein the production transfer function (T_{P}) is determined for various relative image positions (z_{w}), which deviate from an ideal relative image position in an image field of the production system.

12. The method of claim 3, wherein the production transfer function (T_{P}) is determined for various relative image positions (z_{w}), which deviate from an ideal relative image position in an image field of the production system.

13. The method of claim 4, wherein the production transfer function (T_{P}) is determined for various relative image positions (z_{w}), which deviate from an ideal relative image position in an image field of the production system.

14. The method of claim 2, comprising assigning the manipulator positions of the at least one adjustment component (Mᵢ) to the respective illumination setting (σ) and storing the associated data in a lookup table.

15. The method of claim 3, comprising assigning the manipulator positions of the at least one adjustment component (Mᵢ) to the respective illumination setting (σ) and storing the associated data in a lookup table.

16. The metrology system of claim 7, wherein the measurement system is

2. ed to perform the method of claim 2.

17. The metrology system of claim 7, wherein the measurement system is configured to perform the method of claim 3.

18. The metrology system of claim 7, wherein the measurement system is

4. ed to perform the method of claim 4.

19. The metrology system of claim 7, wherein the measurement system is

5. ed to perform the method of claim 5.

20. The metrology system of claim 7, wherein the measurement system is

6. ed to perform the method of claim 6.
